(19) United States
(12) Patent Application Publication
(10) Pub. No.: US 2016/0163947 A1
(43) Pub. Date: Jun. 9, 2016

(54) STRUCTURE FOR MOUNTING THERMOELECTRIC GENERATION ELEMENT MODULE

(71) Applicant: HYUNDAI MOTOR COMPANY, Seoul (KR)

(72) Inventors: Seung Woo LEE, Seoul (KR); Hong Kil BAEK, Seoul (KR); Tae Won LEE, Incheon (KR)

(21) Appl. No.: 14/951,232

(22) Filed: Nov. 24, 2015

(30) Foreign Application Priority Data
Dec. 4, 2014 (KR) 10-2014-0172874

(51) Int. Cl. H01L 35/30; F01N 5/02; H01L 35/32

(52) U.S. Cl. CPC H01L 35/30; H01L 35/32; F01N 5/025

(57) ABSTRACT

A structure for mounting a thermoelectric generation element module for a vehicle includes a thermoelectric generation element module engine including a thermoelectric generation element receiving heat from a heat source to generate electricity; and a gap-adjusting member adjusting a gap between the thermoelectric generation element and the heat source.

### CROSS-REFERENCE TO RELATED APPLICATION

This application claims the benefit of priority to Korean Patent Application No. 10-2014-0172874, filed in the Korean Intellectual Property Office on Dec. 4, 2014, the entirety of which is incorporated herein by reference.

### TECHNICAL FIELD

The present disclosure relates to a structure for mounting a thermoelectric generation element module for a vehicle. More particularly, the present disclosure relates to a structure for mounting a thermoelectric generation element module for a vehicle capable of being away from or close to heat source depending on a heat generation amount of the heat source.

### BACKGROUND

Generally, among heat energy generated by an internal combustion engine of a vehicle, waste heat energy thrown out via exhaust gas is about 20% to 40%. Thus, various techniques for increasing energy efficiency by collecting a part of the waste heat energy of the exhaust gas have been developed.

In particular, regarding waste heat recovery systems that have been applied to a vehicle, thermoelectric generation systems that collect waste heat generated by an engine of a vehicle and transmitted through an exhaust pipe to convert it to electric energy have been researched.

The thermoelectric generation system uses the so-called Zeebeck effect that generates electromotive force by using a temperature difference, and has a thermoelectric generation element or an element module installed at an exhaust system of an engine and a water-cooled cooling system, and so on.

FIG. 1 shows a perspective view of a structure for mounting a thermoelectric generation element module of a thermoelectric generation system applied to a vehicle according to the related art. A thermal insulation plate 20 is installed around an exhaust manifold 10 in order to prevent the heat generated by the exhaust manifold 10 from being spread around it. The thermal insulation plate 20 is installed in order to block an upper surface and a side surface of the exhaust manifold 10 substantially. A thermoelectric generation element module 30 is coupled to and supported by the upper surface and the side surface of the exhaust manifold 10.

Referring to FIG. 2, the thermoelectric generation element module 30 may include a hot spreader 32 being stacked on the thermal insulation plate 20 and directly receiving heat from the heat insulation plate 20, a thermoelectric generation element 34 receiving heat from the hot spreader 32 to generate electricity, a cold spreader 36 being heat-exchanged with the thermoelectric generation element 34 to generate a temperature difference to the thermoelectric generation element 34 and a water jacket 38 cooling the cold spreader 36.

However, in the mounting structure of the thermoelectric generation element module as described above, the thermoelectric generation element module 34 is installed spaced apart from the thermal insulation plate 20 at a constant gap. Thus, if high-temperature heat is emitted from the exhaust system with the engine driven at high speed and high load, there are concerns that the thermoelectric generation elements could receive excessive heat and suffer thermal damage.

Furthermore, when the engine is driven at low speed and low load, electricity generation output is small due to receiving low heat. Electricity generation output is large, however, when the received heat is high, so stable electricity generation is not maintained.

The above information disclosed in this Background section is only for enhancement of understanding of the background of the disclosure and therefore it may contain information that does not form the prior art that is already known in this country to a person of ordinary skill in the art.

### SUMMARY

The present disclosure has been made in an effort to provide a structure for mounting a thermoelectric generation element module for a vehicle capable of getting stable and constant electricity generation output even when the conductive heat amount transferred from an engine varies depending on the driving conditions of the engine and preventing thermoelectric generation elements from suffering heat damage due to excessive heat conduction from the engine.

A structure for mounting a thermoelectric generation element module for a vehicle according to an exemplary embodiment of the present invention may include: a thermoelectric generation element module engine including a thermoelectric generation element receiving heat amount from heat source such as an engine or exhaust system thereof to generate electricity; and a gap-adjusting member adjusting a gap between the thermoelectric generation element and the heat source.

The gap-adjusting member may adjust the gap depending on a heat amount supplied from the heat source.

The gap-adjusting member may be made of shape-memory alloy.

The gap-adjusting member may be formed of a U-shape.

The gap-adjusting member may be formed of an ellipse shape.

The exhaust system may include an exhaust manifold inducing exhaust gas combusted at the engine to outside; and the thermoelectric generation element module may be installed at the exhaust manifold.

A thermal insulation plate or separate structure may be installed at the exhaust manifold; and the thermoelectric generation element module may be installed at the thermal insulation plate or the separate structure via the gap-adjusting member.

The thermoelectric generation element module may be installed at an upper surface, a side surface or all of the upper surface and the side surface of the thermal insulation plate via the gap-adjusting member.

The thermoelectric generation element module may include a hot spreader installed at the thermal insulation plate; the thermoelectric generation element stacked on the hot spreader; a cold spreader stacked on the thermoelectric generation element to heat-exchange with the thermoelectric generation element; and a water jacket installed to cool the cold spreader.

The exhaust system may include an exhaust manifold inducing exhaust gas combusted at the engine to outside; a thermal insulation plate or separate structure may be installed at the exhaust manifold; the gap-adjusting member may be formed of shape-memory alloy to be installed at the thermal insulation plate or the separate structure; the thermoelectric generation element may be mounted at the gap-adjusting member; a cold spreader may be stacked on the thermoelectric generation element to heat-exchange with the thermoelectric generation element; a water jacket may be installed to cool the cold spreader.

By a structure for mounting a thermoelectric generation element module according to an exemplary embodiment of the present invention, in a case that the heat amount conducted and radiated from heat source such as exhaust system of an engine is large due to the engine driven at high speed and high load, a gap-adjusting member receives a large heat amount also to be extendedly deformed such that the thermoelectric generation element module installed at the gap-adjusting member is away from the heat source, thereby preventing the thermoelectric generation elements of the thermoelectric generation element module from suffering heat damage or heat injury due to excessive received hear amount.

Meanwhile, in a case that the heat amount conducted and radiated from heat source such as exhaust system of an engine is small due to the engine driven at low speed and low load, the gap-adjusting member receives a small heat amount also to be contractibly deformed toward the heat source such that the thermoelectric generation element module installed at the gap-adjusting member is closely disposed toward the heat source to receive more heat amount, whereby the thermoelectric generation elements can embody maximum electric generation efficiency, the embodiment of the maximum electric generation efficiency can be achieved over the entire driving range of the engine and the electric generation deviation depending on the driving conditions of the engine can be reduced at a minimum.

### BRIEF DESCRIPTION OF THE DRAWINGS

FIG. 1 is a perspective view of a thermoelectric generation element module installed at exhaust system of an engine according to the related art.

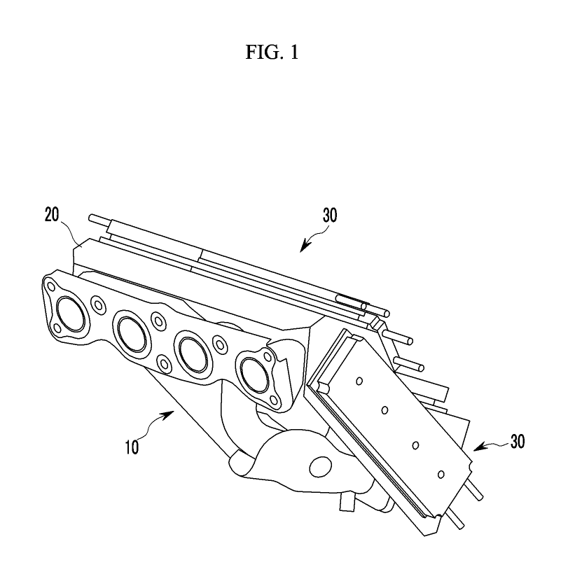

FIG. 2 is an enlarged perspective view of a thermoelectric generation element module according to the related art.

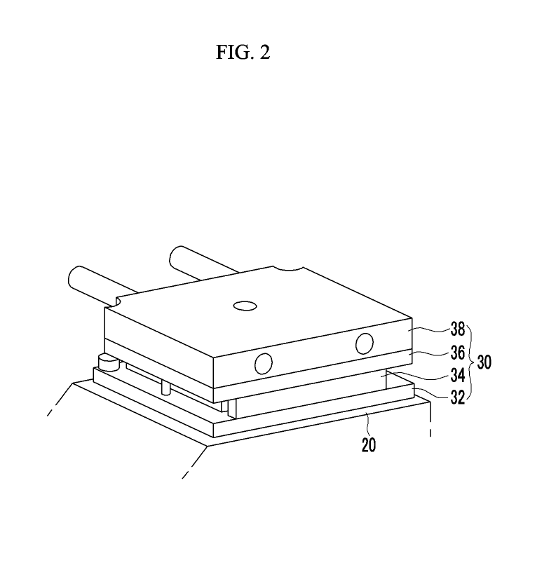

FIG. 3 is a perspective view of a structure for mounting a thermoelectric generation element module according to an exemplary embodiment of the present invention.

FIG. 4 is an operating state diagram when the thermoelectric generation element module according to an exemplary embodiment of the present invention receives excessive heat amount from heat source.

### DETAILED DESCRIPTION OF THE EMBODIMENTS

Hereinafter, an exemplary embodiment of the present invention will be described in detail with reference to the accompanying drawings.

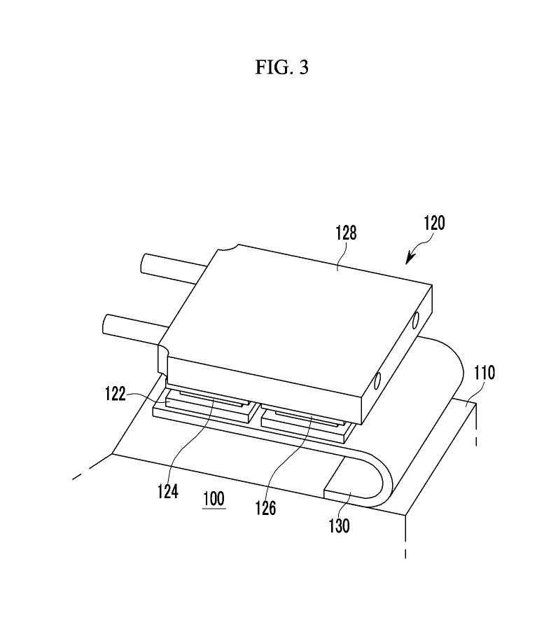

Referring to FIG. 3, a structure for mounting a thermoelectric generation element module according to an exemplary embodiment of the present invention may be applied to an exhaust manifold 100 as a constituent element of an exhaust system of an engine.

Of course, it may be applied to another constituent element of the exhaust system other than the exhaust manifold 100, such as an exhaust pipe.

The exhaust manifold 100 may play a role of collecting exhaust gas generated at each combustion chamber of the engine and inducing it to be discharged to the outside of the vehicle. The exhaust manifold 100 may emit high-temperature heat of the exhaust gas flowed therein.

Due to the high-temperature emission like this, a thermal insulation plate 110 may be installed at the exhaust manifold 100 in order to prevent engine peripheral components from suffering heat damage.

The thermal insulation plate 110 may be installed to cover an upper surface in a height direction of the vehicle and a side surface in a width direction of the vehicle in the exhaust manifold 100.

The thermal insulation plate 110 may be formed so that the heat of the exhaust manifold 100 is directly transmitted to a thermoelectric generation element and hot spreader associated part of a thermoelectric generation element module is opened.

In order to receive the heat amount conducted and radiated from the thermal insulation plate 110 to generate electricity, a thermoelectric generation element module 120 may be disposed closely to the thermal insulation plate 110.

The thermoelectric generation element module 120 may include a hot spreader 122 being disposed closely to the thermal insulation plate 110 and directly receiving heat from the thermal insulation plate 110, at least one thermoelectric generation element 124 receiving heat from the hot spreader 122 to generate electricity, a cold spreader 126 being heat-exchanged with the thermoelectric generation element 124 and generating temperature difference to the thermoelectric generation element 124, and a water jacket 128 cooling the cold spreader 126.

The thermoelectric generation element module 120 may be installed at the thermal insulation plate 110 via the gap-adjusting member 130 to be close to or away from a heat source such as the exhaust manifold 100 and the thermal insulation plate 110.

The gap-adjusting member 130 may have a shape having a cross-section which is substantially bent like “U”.

The gap-adjusting member 130 may be formed so that the cross-section thereof has a substantial ellipse. The thermoelectric generation element module 120 may be installed on one side of the ellipse cross-section.

The gap-adjusting member 130 may be formed with shape-memory alloy of which the shape is varied depending on the temperature.

The thermoelectric generation element module 120 may be installed at an upper surface, a side surface, or all of the upper surface and the side surface of the exhaust manifold 100 via the gap-adjusting member 130.

FIG. 3 shows the gap-adjusting member 130 maintaining its original U-shape in a case that the engine is driven at low speed and low load, that is, the heat amount emitted from the exhaust manifold 100 is small, such that the thermoelectric generation element module 120 is disposed close to the exhaust manifold 100 and the thermal insulation plate 110.

Therefore, the thermoelectric generation element 124 receives an appropriate heat amount from the exhaust manifold 100 and the thermal insulation plate 110 to generate electricity at maximum generation efficiency.

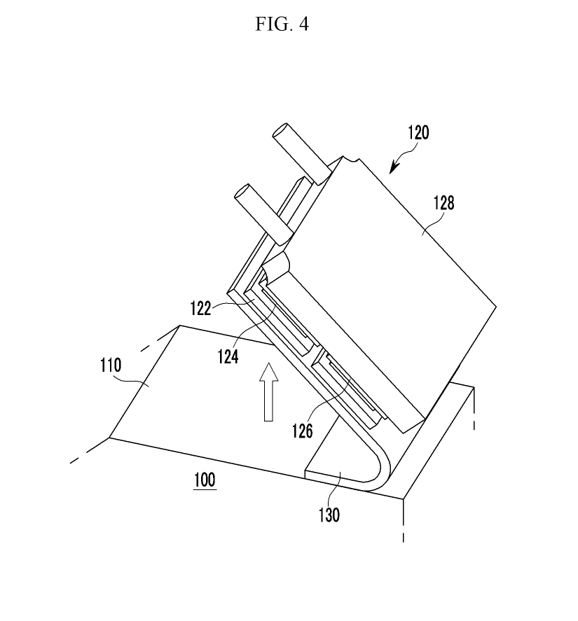

Referring to FIG. 4, in a case where the heat amount conducted and radiated from the exhaust manifold 100 is high by the engine driven at high speed and high load, the gap-adjusting member 130 receives enough heat amount so that it is thermally deformed to bend away from the exhaust manifold 100 as shown. Thus, the thermoelectric generation element module 120 mounted at the gap-adjusting member 130 is away from the exhaust manifold 100, thereby preventing the thermoelectric generation element of the thermoelectric generation element module 120 from suffering heat damage by receiving an excessive heat amount.

Even if it is described that the thermoelectric generation element module 120 is installed at the thermal insulation plate 110 in the exemplary embodiment of the present invention, the thermoelectric generation element module 120 may be installed to be close to the heat source without using the thermal insulation plate 110 or installed at a separate structure other than the thermal insulation plate 110.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A structure for mounting a thermoelectric generation element module for a vehicle, comprising:
a thermoelectric generation element module engine including a thermoelectric generation element receiving heat from a heat source to generate electricity; and
a gap-adjusting member adjusting a gap between the thermoelectric generation element and the heat source.

2. The structure of claim 1, wherein:
the gap-adjusting member adjusts the gap depending on an amount of heat supplied from the heat source.

3. The structure of claim 1, wherein:
the gap-adjusting member is made of a shape-memory alloy.

4. The structure of claim 1, wherein:
the gap-adjusting member is formed to have a U-shape.

5. The structure of claim 1, wherein:
the gap-adjusting member is formed to have an ellipse shape.

6. The structure of claim 1, wherein:
the exhaust system includes an exhaust manifold configured to transmit exhaust gas combusted at the engine to outside of the vehicle; and
the thermoelectric generation element module is installed at the exhaust manifold.

7. The structure of claim 6, wherein:
a thermal insulation plate or a separate structure is disposed on the exhaust manifold; and
the thermoelectric generation element module is installed on the thermal insulation plate or the separate structure via the gap-adjusting member.

8. The structure of claim 7, wherein:
the thermoelectric generation element module is installed at an upper surface, a side surface or all of the upper surface and the side surface of the thermal insulation plate via the gap-adjusting member.

9. The structure of claim 7, wherein:
the thermoelectric generation element module includes:
a hot spreader disposed on the thermal insulation plate;
the thermoelectric generation element stacked on the hot spreader;
a cold spreader stacked on the thermoelectric generation element to heat-exchange with the thermoelectric generation element; and
a water jacket installed to cool the cold spreader.

10. The structure of claim 1, wherein:
the exhaust system includes an exhaust manifold configured to transmit exhaust gas combusted at the engine to outside of the vehicle;
a thermal insulation plate or a separate structure is installed at the exhaust manifold;
the gap-adjusting member is formed of a shape-memory alloy and disposed on the thermal insulation plate or the separate structure;
the thermoelectric generation element is mounted on the gap-adjusting member;
a cold spreader is stacked on the thermoelectric generation element to heat-exchange with the thermoelectric generation element; and
a water jacket is installed to cool the cold spreader.
